(19) United States
(12) Patent Application Publication
(10) Pub. No.: US 2015/0303268 A1
(43) Pub. Date: Oct. 22, 2015

(54) DIODE AND POWER CONVERSION DEVICE

(71) Applicant: HITACHI POWER SEMICONDUCTOR DEVICE, LTD., Hitachi-shi, Ibaraki (JP)

(72) Inventors: Tetsuya Ishimaru, Tokyo (JP); Mutsuhiro Mori, Tokyo (JP)

(73) Assignee: Hitachi Power Semiconductor Device, Ltd., Hitachi-shi, Ibaraki (JP)

(21) Appl. No.: 14/646,375

(22) PCT Filed: Dec. 3, 2013
(86) PCT No.: PCT/JP2013/082454

§ 371 Date: May 20, 2015

(30) Foreign Application Priority Data
Jan. 18, 2013 (JP) 2013-007770

(51) Int. Cl. H01L 29/36; H02M 5/458; H01L 29/861

(52) U.S. Cl. CPC H01L 29/36; H01L 29/861; H02M 5/4585

(57) ABSTRACT

It is an object of the present invention to provide a diode that can be produced with a simple method and performs a favorable recovery operation. The diode in accordance with the present invention includes a layer with a high concentration of dopants and a layer with a low concentration of dopants, and the layer with a low concentration of dopants further includes a layer with a different activation rate from other potions (see FIG. 1).

### TECHNICAL FIELD

The present invention relates to a diode formed using a semiconductor substrate.

### BACKGROUND ART

An electrical power conversion system that converts power through a switching operation has a semiconductor switching element, such as an IGBT (Insulated Gate Bipolar Transistor) or a MOS (Metal-Oxide-Semiconductor) transistor. A diode, which is connected in inverse-parallel with such semiconductor switching element and is used as a free wheeling diode, is further required to have reduced recovery current during a switching operation or have a suppressed sharp rising voltage/ringing during reverse recovery in accordance with an increase in the drive frequency.

In order to suppress a sharp rising voltage/vibration during recovery, there has been proposed a method of providing a local low lifetime layer in a Si substrate on the anode side. When a local low lifetime layer is provided in a Si substrate on the anode side, the number of holes that are injected from the anode decreases. Consequently, the carrier density on the anode side decreases and the carrier density on the cathode side increases when current flows through the diode. When the carrier density on the cathode side increases, the number of carriers that remain in an n− drift layer on the cathode side during recovery increases, so that a sudden reduction in the amount of recovery current is suppressed, and a sharp rising voltage/ringing during reverse recovery is thus suppressed.

Non Patent Literature 1 below proposes a method of using He irradiation or proton irradiation as a method of providing a local low-lifetime layer in a Si substrate on the anode side. In Non Patent Literature 1, a Si substrate is irradiated with He⁺ or protons to form a local low-lifetime layer in the Si substrate on the anode electrode side and thus suppress a sharp rising voltage/ringing during reverse recovery.

Patent Literature 1 below also proposes a method of using ion implantation for forming a p layer on the anode side as another method of forming a local low-lifetime layer in a Si substrate on the anode side. In Patent Literature 1, in order to form a local low-lifetime layer in the Si substrate, p-type dopant ions are implanted into a Si substrate, and then the implanted p-type dopants are partially activated by laser annealing to form a p layer. The local low-lifetime layer suppresses a sharp rising voltage/ringing during reverse recovery.

### CITATION LIST

### Patent Literature

Patent Literature 1: JP Patent Publication (Kokai) 2008-004866 A

### Non Patent Literature

Non Patent Literature 1: K. Nishiwaki, T. Kushida, A. Kawahashi, Proceedings of the 13th International Symposium on Power Semiconductor Devices and ICs (ISPSD) 2001, pp. 235-238, 2001.

### SUMMARY OF INVENTION

### Technical Problem

In the technique described in Non Patent Literature 1, huge particle irradiation equipment like cyclotron is needed to irradiate a substrate with protons or He⁺. Thus, the production cost becomes high. Further, as the weight of protons or He⁺ is light, the width of the distribution of defects formed by proton irradiation or He irradiation in the depth direction is large, and thus, the position in the depth direction cannot be precisely controlled. When the position in the depth direction cannot be precisely controlled, variations in the characteristics of the diode are likely to be larger. Further, when the width of the distribution of defects in the depth direction is large, the conduction loss of the diode increases correspondingly.

In the technique described in Patent Literature 1, the position of defects are introduced by ion implantation in the depth direction is almost the same as the position of the p layer activated by laser annealing in the depth direction. Thus, if the depth of implanted ions or the depth of p layer formed by the laser annealing varies even slightly, the number of defects that remain after the laser annealing vary greatly. This results in large variations in the forward voltage and the recovery loss.

The present invention has been made in view of the foregoing problems, and it is an object of the present invention to provide a diode that can be produced with a simple method and performs a favorable recovery operation.

### Solution to Problem

A diode in accordance with the present invention includes both a layer with a high concentration of dopants and a layer with a low concentration of dopants, and the layer with a low concentration of dopants further includes a layer with an activation rate different from other potions.

### Advantageous Effects of Invention

According to a diode in accordance with the present invention, a diode that can be produced with a simple method and performs a favorable recovery operation can be provided. Other problems, structures, and advantageous effects will become apparent from the following description of embodiments.

### BRIEF DESCRIPTION OF DRAWINGS

FIG. 1 is side sectional view of a diode 1 in accordance with Embodiment 1.

FIG. 2 is a view illustrating a step of implanting ions of a p-type well into a termination region.

FIG. 3 is a view illustrating a step of implanting ions of an n-type well into a termination region.

FIG. 4 is a view illustrating a step of activating and diffusing dopants of an n-type well and a p-type well in a termination region.

FIG. 5 is a view illustrating a step of implanting ions of a p-type well into an active region.

FIG. 6 is a view illustrating a step of activating a p-type well in an active layer to form a low-lifetime layer.

FIG. 7 is a view illustrating a step of forming an anode electrode.

FIG. 8 is a view illustrating a step of forming a cathode buffer n layer 111 and a cathode n layer 112.

FIG. 9 is a view showing a concentration profile of p-type dopants (solid line) and a concentration profile of activated dopants (dashed line) in the depth direction seen from the anode side.

FIG. 10 is a side sectional view of a diode 1 in accordance with Embodiment 2.

FIG. 11 is a side sectional view of a diode 1 in accordance with Embodiment 3.

FIG. 12 is a side sectional view of a diode 1 in accordance with Embodiment 4.

FIG. 13 is a view showing a concentration profile of n-type dopants and a concentration profile of activated n-type dopants in the depth direction seen from the cathode side in Embodiment 4.

FIG. 14 is a circuit diagram of an electrical power conversion system 10 in accordance with Embodiment 5.

FIG. 15 is a diagram showing current waveforms and voltage waveforms of the recovery characteristics at room temperature of diodes.

FIG. 16 is a diagram showing a forward voltage and turn-on loss at 150° C. when the depth at which p-type dopants are activated by laser annealing on the anode side varies.

FIG. 17 is a diagram showing a sharp rising voltage during recovery at room temperature when the depth at which p-type dopants are activated by laser annealing on the anode side varies.

FIG. 18 is a diagram showing current waveforms and voltage waveforms of the recovery characteristics at room temperature.

### DESCRIPTION OF EMBODIMENTS

Hereinafter, embodiments of the present invention will be described in detail with reference to the drawings. It should be noted that portions having the same function throughout the drawings for illustrating the embodiments are denoted by the same reference numerals, and the description thereof will be omitted as appropriate. In addition, in the following embodiments, portions that are the same or similar will be described only once unless otherwise necessary.

Although the following embodiments will describe an example of a diode for which an n-type Si substrate is used, where a first conductivity type is an n-type and a second conductivity type is a p-type, the present invention is not limited thereto. A case where a p-type Si substrate is used, where a first conductivity type is a p-type and a second conductivity type is an n-type, can be considered the same way as when an n-type Si substrate is used.

### Embodiment 1: Structure of Diode

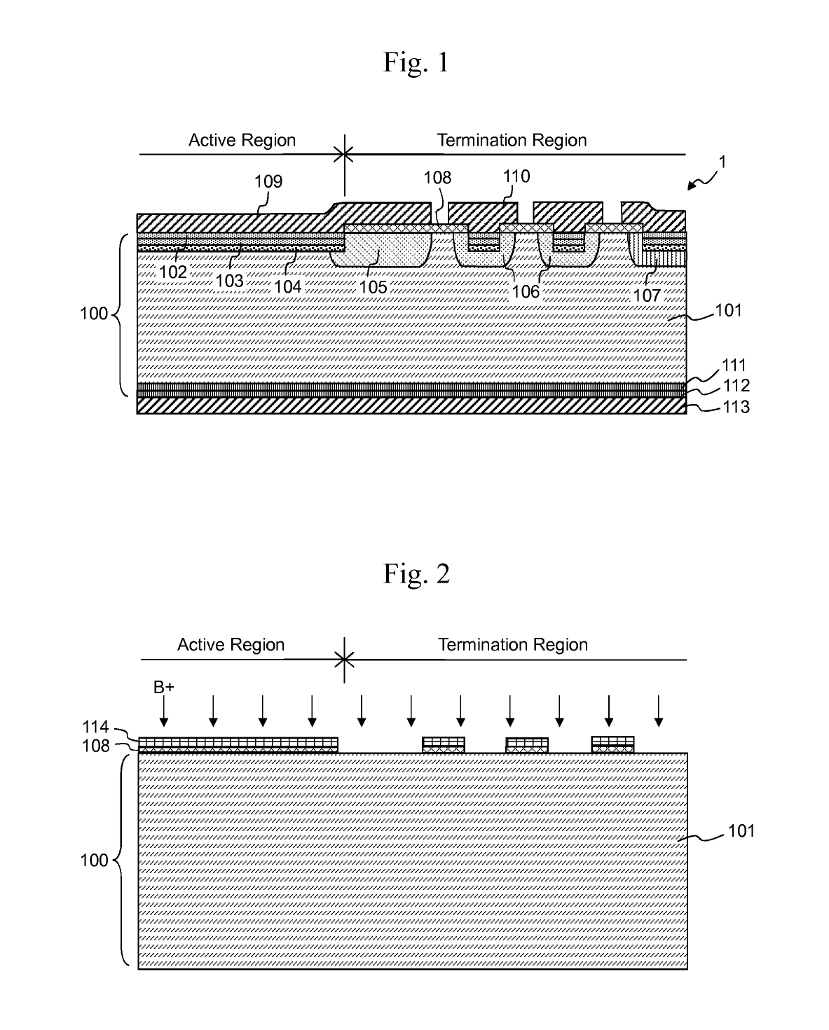

FIG. 1 is side sectional view of a diode 1 in accordance with Embodiment 1 of the present invention. FIG. 1 shows a schematic sectional view of an active region and a termination region of the diode 1. In the following description, the entire portion of the semiconductor layer in the production steps including a middle stage will be referred to as a Si substrate 100.

The structure of the active region of the diode 1 includes, as shown in FIG. 1, an n− drift layer 101, an anode p layer 102, an anode p− layer 103, a low lifetime region layer 104, a cathode n layer 112, a cathode buffer n layer 111, an anode electrode 109, and a cathode electrode 113.

The n− drift layer (i.e., first semiconductor layer) 101 is a semiconductor layer containing n-type Si that is an n-type semiconductor layer including an n-type semiconductor region, which is not modified by ion implantation, diffusion, or the like, of the original n-type Si substrate.

The anode p layer (i.e., third semiconductor layer) 102 is a p-type semiconductor layer that is provided in the active region on the outermost surface on the anode side that is the front surface side of the Si substrate 100 and includes a p-type dopant region.

The anode p− layer 103 is provided at a position adjacent to the anode p layer 102 on the anode side that is the front surface side of the Si substrate 100, and is a p-type semiconductor layer including a p-type dopant region with a lower concentration than the anode p layer 102.

The low lifetime region layer 104 is a semiconductor layer formed at a position adjacent to the anode p− layer 103 or in the anode p− layer 103 on the anode side that is the front surface side of the Si substrate 100. The lifetime of minority carriers in the low lifetime region layer 104 is shorter than that of the n− drift layer 101. The low lifetime region layer 104 contains as p-type dopants the same type of dopants (element) as the p-type dopants contained in the anode p− layer 103.

The structures of such p-type semiconductor layers will be described in detail along with [Conditions of Ion Implantation and Laser Annealing] described later.

The cathode n layer (i.e., second semiconductor layer) 112 is an n-type semiconductor layer that is provided on the cathode side that is the back surface side of the Si substrate 100 and includes an n-type dopant region with a higher concentration than the n− drift layer 101.

The cathode buffer n layer 111 is an n-type semiconductor layer that is provided adjacent to the cathode n layer 112 on the n− drift layer 101 side and includes an n-type dopant region with a lower concentration than the cathode n layer 112 and with a higher concentration than the n− drift layer 101. The cathode buffer n layer 111 may be omitted, but providing the cathode buffer n layer 111 can suppress the expansion of a depletion layer toward the anode side from the PN junction when a reverse voltage is applied to the diode 1, and thus improve the breakdown voltage of the diode 1.

The anode electrode (i.e., first electrode) 109 is an electrode that is ohmic-connected to the anode p layer 102. The cathode electrode (i.e., second electrode) 113 is an electrode that is ohmic-connected to the cathode n layer 112.

The structure of the termination region of the diode 1 includes, as shown in FIG. 1, the n− drift layer 101, the cathode n layer 112, the cathode buffer n layer 111, the anode electrode 109, and the cathode electrode 113 that are common to the active region, and also includes a p-type well region 105 with a HIRC (High Reverse Recovery dI/dt Capability) structure, a p-type well region 106 with a FLR (Field Limiting Ring) structure, a field plate electrode 110, and an n-type well region 107 functioning as a channel stopper.

The p-type well region 105 with the HIRC structure is a p-type semiconductor layer including a p-type dopant region that is ohmic-connected to the anode electrode 109 only at the end portion on the active region side. Providing the p-type well region 105 can prevent breakdown that would otherwise occur due to carriers concentrated at the end portion of the active region during recovery. The p-type well region 105 with the HIRC structure may be omitted if there is no problem with the breakdown withstand capacity during reverse recovery.

The p-type well region 106 with the FLR structure is a p-type semiconductor layer including a p-type dopant region that is arranged in a ring shape in the termination region. The field plate electrode 110 is an electrode that is arranged in a ring shape in the termination region and is ohmic-connected to the p-type well region 106 with the FLR structure. Providing the p-type well region 106 with the FLR structure and the field plate electrode 110 can relax an electric field at the end portions of the p-type well region 106 with the FLR structure and can thus ensure the breakdown voltage. Although FIG. 1 shows an exemplary structure in which two p-type well regions 106 with the FLR structure and two field plate electrodes 110 are provided, such components may be provided in necessary number in accordance with the breakdown voltage of the chip.

The n-type well region 107 is an n-type semiconductor layer including an n-type dopant region that is provided on the outermost region of the chip. Providing the n-type well region 107 can suppress the expansion of a depletion layer from the p-type well region 105 upon application of a high voltage in the reverse direction.

Although FIG. 1 shows an example in which the FLR structure is used as the termination structure, it is also possible to use a termination structure, such as a JTE (Junction Termination Extension) structure in which another p-type well region with a low concentration of dopants is arranged adjacent to the p-type well region 105.

### Embodiment 1: Method for Producing Diode

Next, an exemplary method for producing the diode 1 will be described with reference to FIGS. 2 to 8 (and also with reference to FIG. 1 as needed).

### (Preparation of Substrate)

First, a Si wafer is prepared as the Si substrate 100 for producing the diode 1. For the Si wafer, a FZ (Floating Zone) wafer with the resistivity corresponding to the breakdown voltage is used. In Embodiment 1, a bulk of a FZ wafer is used as the n− drift layer 101. The resistivity of the FZ wafer can be about 25 Ωcm for a diode with a breakdown voltage of 600 V, and can be about 55 Ωcm for a diode with a breakdown voltage of 1.2 kV, for example.

(Step of Implanting ions of p-Type Well into Termination Region)

FIG. 2 is a view illustrating a step of implanting ions of a p-type well into the termination region. First, the entire surface of the Si substrate 100 is thermally oxidized to form an oxide film 108. Next, a photolithography step for forming a well region in the termination region is performed. In the photolithography step, a resist material is applied to the surface of the Si substrate 100 and is then exposed to light and developed, whereby a resist 114 is formed that has openings in regions where the p-type well region 105 with the HIRC structure, the p-type well region 106 with the FLR structure, and the n-type well region 107 functioning as a channel stopper are to be formed. After that, the oxide film exposed at the openings of the resist 114 is removed by wet etching using the resist 114 as a mask. Further, p-type dopant ions for forming the p-type well region 105 with the HIRC structure and the p-type well region 106 with the FLR structure are implanted using the resist 114 as a mask. At this time, p-type dopant ions are also implanted into a region in which the n-type well 107 is to be formed. As the conditions for implanting p-type dopant ions, boron is used as the ion species, the energy is set to 75 keV, and the dose is set to 2×10¹³/cm², for example. After the ions are implanted, the resist 114 is removed.

(Step of Implanting ions of N-Type Well into Termination Region)

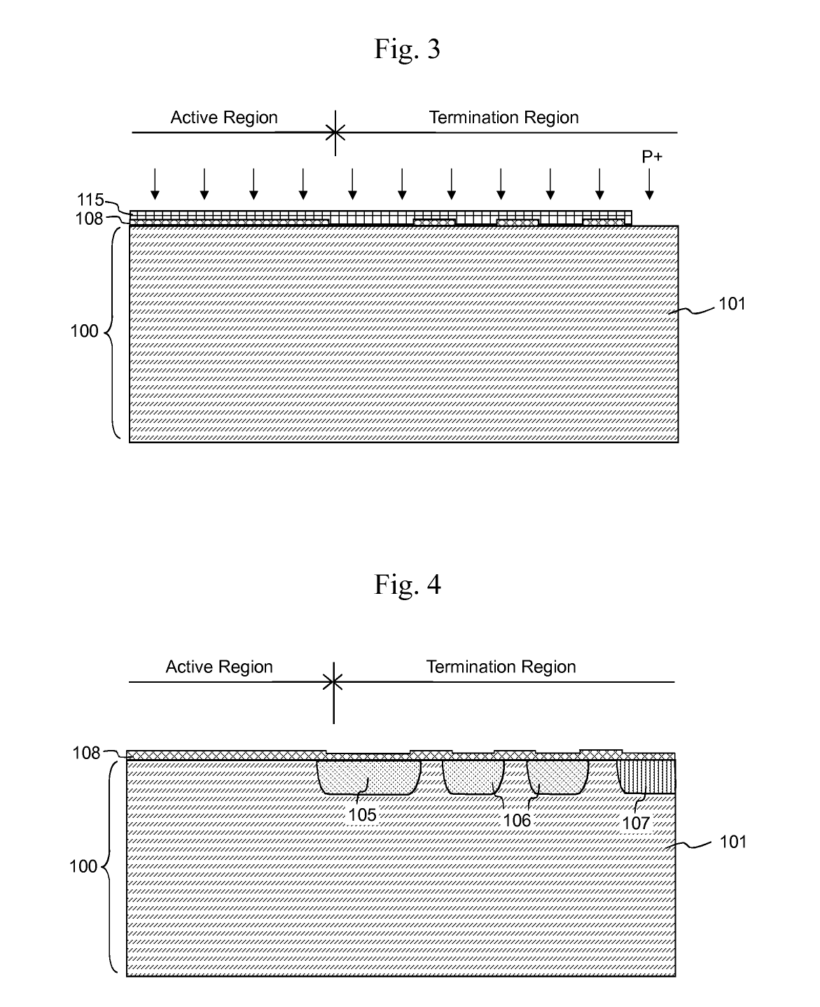

FIG. 3 is a view illustrating a step of implanting ions of an n-type well into a termination region. First, a photolithography step for forming the n-type well region 107 functioning as a channel stopper is performed. In the photolithography step, a resist material is applied to the surface of the Si substrate 100 and is then exposed to light and developed, whereby a resist 115 is formed that has an opening in a region in which the n-type well 107 functioning as a channel stopper is to be formed. After that, n-type dopant ions for forming the n-type well region 107 are implanted using the resist 115 as a mask. As the conditions for implanting n-type dopant ions, phosphorus is used as the ion species, the energy is set to 75 keV, and the dose is set to 1×10¹⁵/cm², for example. P-type dopants are also implanted into the region in which the n-type well 107 is to be formed in the step shown in FIG. 2. Because the concentration of p-type dopants is sufficiently lower than that of the n-type dopants, an n-type well is finally formed. After the ions are implanted, the resist 115 is removed.

### (Step of Diffusing N-Type and P-Type Wells in Termination Region)

FIG. 4 is a view illustrating a step of activating and diffusing the dopants in the n-type well and the p-type well in the termination region. The diffusion conditions are set to 1200° C. and 120 minutes, for example. Through the diffusion step, the wells with a junction depth as deep as 5 to 10 μm are formed. Forming the deep wells can ensure the breakdown voltage of the termination region. Along with this step, annealing is performed in an oxygen atmosphere to grow the oxide film 108.

(Step of Implanting Ions of P-Type Well into Active Region)

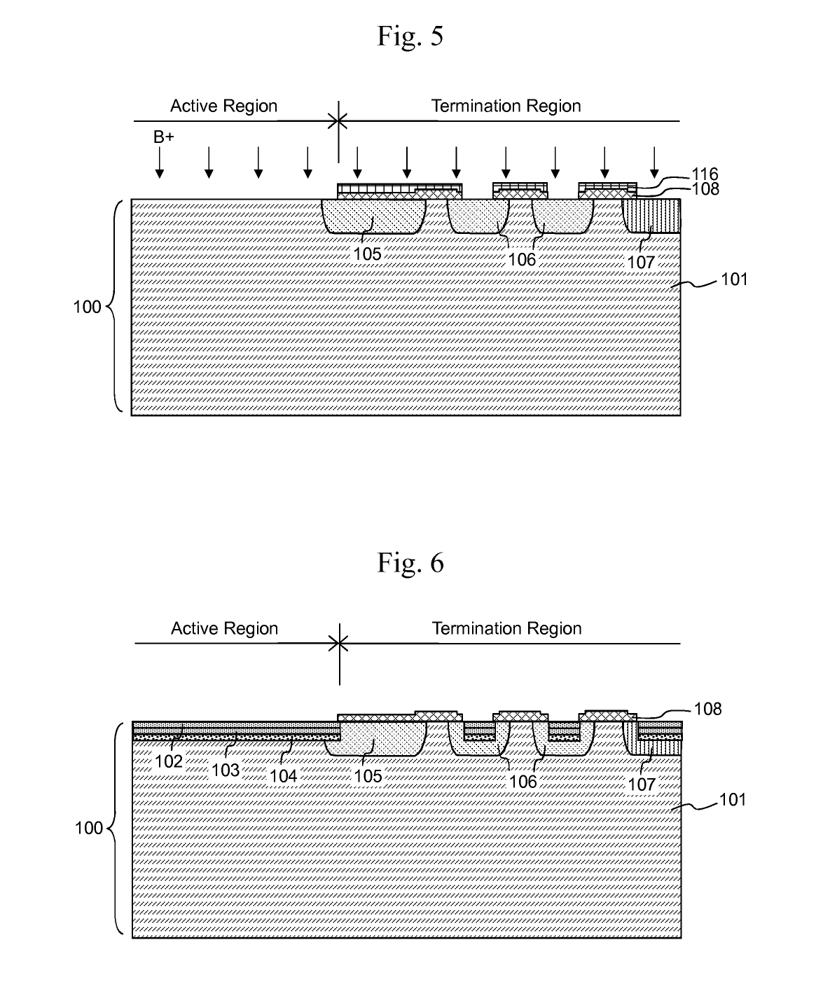

FIG. 5 is a view illustrating a step of implanting ions of the p-type well into the active region. First, a photolithography step for forming the anode p layer 102, the anode p− layer 103, and the low-lifetime region layer 104 in the active region is performed. In the photolithography step, a resist material is applied to the surface of the Si substrate 100 and is then exposed to light and developed, whereby a resist 116 is formed to have openings in the entire surface of the active region and in regions where contacts with the p-type well region 106 and the n-type well region 107 are to be formed in the termination region. After that, implantation of p-type dopant ions for forming the anode p− layer 103 and implantation of p-type dopant ions for forming the anode p layer 102 are performed using the resist 116 as a mask. The implantation of p-type dopant ions for forming the anode p− layer 103 is performed so that the ions are implanted with a lower concentration than and with a higher implantation energy than the implantation of p-type dopant ions for forming the anode p layer 102. The implantation of p-type dopant ions for forming the anode p− layer 103 is performed under the conditions that boron is used as the ion species, the energy is set to 720 keV, and the dose is set to 1×10¹²/cm², for example. The implantation of p-type dopant ions for forming the anode p− layer 102 is performed under the conditions that boron is used as the ion species, the energy is set to 25 keV, and the dose is set to 1×10¹⁴/cm², for example. After the ions are implanted, the resist 116 is removed.

(Step of Activating P-Type Well in Active Region and thus Forming Low Lifetime Layer)

FIG. 6 is a view illustrating a step of activating the p-type well in the active layer and thus forming a low-lifetime layer. First, laser annealing is performed to activate the implanted p-type dopant ions. When the surface of the Si substrate 100 on the anode side is irradiated with laser, only a region around the Si surface in the opening of the oxide film 108 is heated, and thus, only the p-type dopants around the Si surface are activated. In addition, regarding defects that are formed by ion implantation, only the defects located around the Si surface are recovered. The surface of the Si substrate 100 that is covered with the oxide film 108 is not heated to a high temperature as the thermal conductivity of the oxide film is low. The depth at which the p-type dopants are activated and the depth at which the defects are recovered can be changed depending on the laser irradiation conditions. For example, lowering the energy of laser irradiation can deepen the depth at which the p-type dopants are activated and the depth at which the defects are recovered. Selecting the laser irradiation conditions can form the anode p layer 102 and the anode p− layer 103 by sufficiently activating some of the p-type dopants in the anode p layer 102 and the anode p− layer 103 on the front surface side, and also form the low-lifetime region layer 104 without recovering defects that are formed at a deep position by the high-energy ion implantation for forming the anode p− layer 103. The low-lifetime region layer 104 is a region where the lifetime of minor carriers is shortened by the defects generated by the ion implantation.

The p-type well region 106 and the n-type well region 107 in the termination region also have the anode p layer 102, the anode p− layer 103, and the low-lifetime region layer 104 therein. However, because a region around such layers is covered with the p-type well region 106 and the n-type well region 107, even if a depletion layer expands upon application of a high voltage, the depletion layer does not reach the anode p layer 102, the anode p− layer 103, or the low-lifetime region layer 104. Thus, no problem in operation will arise.

As a laser used for laser annealing, the second harmonic of a YLF (Yttrium Lithium Fluoride) laser with a wavelength of 536 nm, a YAG (Yttrium Aluminum Garnet) laser with a similar wavelength: 532 nm, a YVO4 laser with a wavelength of 532 nm, or the like can be used. Further, it is also possible to use a XeCl excimer laser with a further shorter wavelength: 308 nm or a KrF excimer laser with a wavelength of 248 nm. The energy and wavelength of laser irradiation can be appropriately selected in accordance with the depth at which the p-type dopants are activated and the depth at which the defects are recovered. The detailed conditions of the ion implantation and laser annealing will be described later.

### (Step of Forming Anode Electrode)

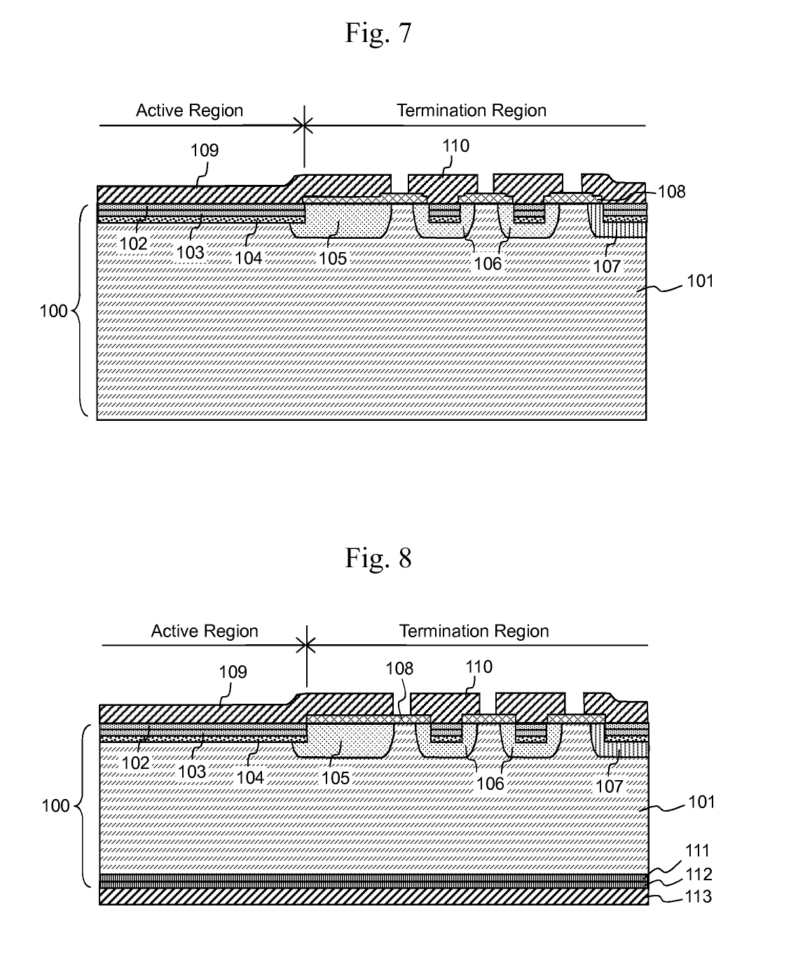

FIG. 7 is a view illustrating a step of forming the anode electrode. After preliminary washing is performed, a film made of a conductive material to be the anode electrode 109, for example, an AlSi film is formed by sputtering or deposition. Next, a photolithography step and an etching step for forming the field plate electrode 110 in the termination region are performed, whereby the field plate electrode 110 is formed. At this time, the AlSi film that remains on the entire surface of the active region becomes the anode electrode 109. Etching of the AlSi film is performed by wet etching or dry etching. After the AlSi film is etched, the resist is removed.

Next, though not shown, a protective film is formed in the termination region after the resist for processing the electrode provided in the termination region is removed. As a method for forming a protective film, for example, a solution containing a polyimide precursor material and a photosensitive material is applied, and the termination region is exposed to light to turn the precursor into polyimide, so that a polyimide protective film can be formed in the termination region.

Through the above steps, the structure on the anode side is completed. Hereinafter, steps of forming the structure on the cathode side will be described.

### (Step if Polishing Rear Surface)

First, the back surface of the Si wafer that is the Si substrate 100 is ground to reduce the wafer thickness. The wafer thickness differs depending on the breakdown voltage of the diode 1. For example, the wafer thickness of a product with a breakdown voltage of 600 V is about 70 μm, and the wafer thickness of a product with a breakdown voltage of 1200 V is about 120 μm. In order that a layer damaged by the grinding will not remain, chemical etching is preferably performed after mechanical polishing. For example, when the diameter of the Si substrate 100 is large like an 8-inch wafer, a grinding method called TAIKO grinding (“TAIKO” is a registered trademark) is preferably used to avoid wafer cracking. Such a grinding method is a grinding method that leaves a thick wafer portion in a ring shape around the wafer. It should be noted that such grinding of the back surface of the Si wafer need not be performed for a diode with a breakdown voltage of greater than or equal to 3.3 kV as the finished Si wafer is thick.

### (Step of Forming Cathode Buffer n Layer/Cathode n Layer)

FIG. 8 is a view illustrating a step of forming the cathode buffer n layer 111 and the cathode n layer 112. After the back surface of the Si substrate 100 is ground, n-type dopant ions for forming the cathode buffer n layer 111 and the cathode n layer 112 are sequentially implanted to the entire wafer surface of the Si substrate 100 from the back surface side. The implantation of n-type dopant ions for forming the cathode buffer n layer 111 is performed so that the ions are implanted with a lower concentration than and a higher implantation energy than the implantation of n-type dopant ions for forming the cathode n layer 112. The implantation of n-type dopant ions for forming the cathode buffer n layer 111 is performed under the conditions that phosphorus is used as the ion species, the energy is set to 720 keV, and the dose is set to 1×10¹²/cm², for example. The implantation of n-type dopant ions for forming the cathode n layer 112 is performed under the conditions that phosphorus is used as the ion species, the energy is set to 45 keV, and the dose is set to 1×10¹⁵/cm², for example. Providing the cathode buffer n layer 111 can suppress a decrease in yield due to defects on the back surface, but the cathode buffer n layer 111 need not be provided.

Next, laser annealing is performed to activate the implanted n-type dopant ions. When activation is performed using laser annealing, the n-type dopants on the back surface side can be activated without the electrode and a protective film (not shown), which are formed on the front surface side that is the anode side of the Si substrate 100, heated to a temperature that is greater than or equal to the heat resistant temperature. The same type of laser as the laser used for annealing to activate the anode p layer 102 and the anode p− layer 103 may be used.

### (Step of Forming Cathode Electrode)

After the laser annealing is performed, the cathode electrode 113 is formed on the back surface that is the cathode side. The cathode electrode 113 can be formed with a similar method to the method for forming the anode electrode 109, using an appropriate conductive material such as metal. After that, laser beam irradiation is performed from the back surface side to adjust the lifetime of carries in the entire region of the wafer, and further, an annealing process is performed to recover the damage due to the electron beam irradiation. (Splitting Step)

Finally, the wafer is split using dicing or the like, so that the chip of the diode 1 is completed.

### Embodiment 1: Conditions of Ion Implantation and Laser Annealing

Next, the conditions of ion implantation and laser annealing for forming the anode p layer 102, the anode p− layer 103, and the low-lifetime region layer 104 in the active region will be described. When the depth at which the concentration of defects generated by ion implantation is peak is shallower than the depth at which the implanted p-type dopant ions are activated by laser annealing, even a slight variation in the depth of ion implantation or the depth of activation by means of laser annealing results in large variations in the electrical characteristics. In order to suppress the variations in the electrical characteristics, the depth at which the concentration of defects generated by ion implantation is peak should be deeper than the depth at which the implanted p-type dopant ions are activated by laser annealing. When the defect layer is provided at a deep position, it is possible to reduce variations in the amount of defects that remain in the low-lifetime region layer 104 resulting from variations in the depth direction of the defect distribution and variations in the depth direction of a position at which activation is performed by laser annealing.

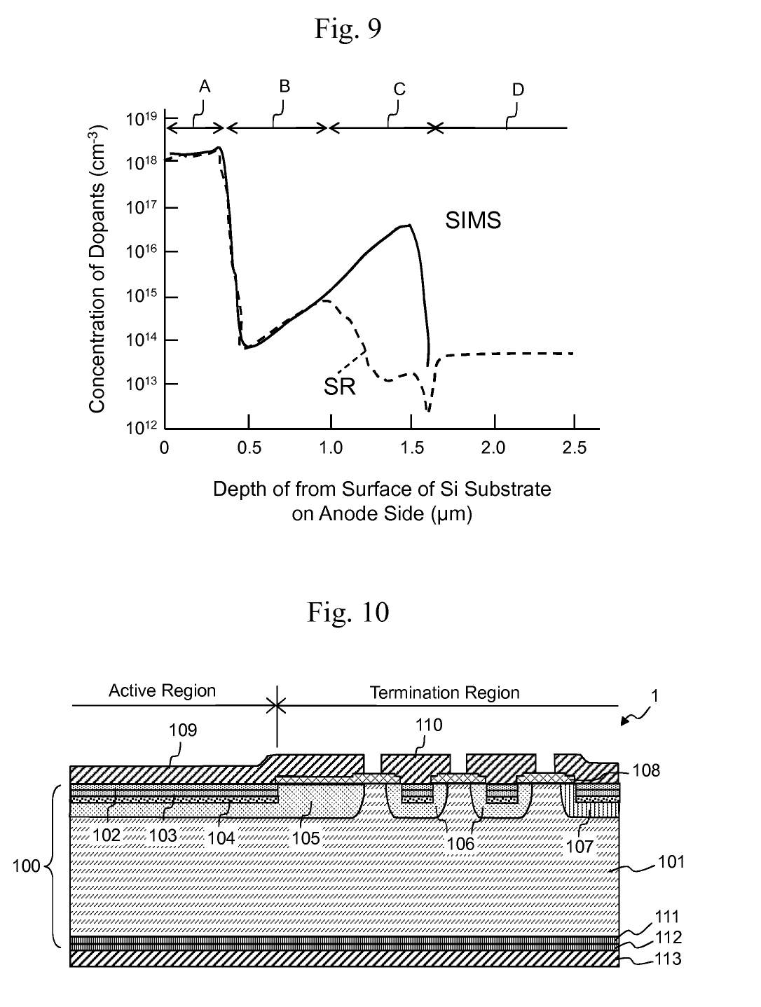

FIG. 9 is a view showing a concentration profile of the p-type dopants (solid line) and a concentration profile of activated dopants (dashed line) in the thickness direction seen from the front surface side, that is, the anode side of the Si substrate 100 of the diode 1 produced under the conditions described below. The structure in the depth direction of the p-type semiconductor layer on the anode side will be described with reference to FIG. 9 (and also with reference to FIG. 1 as needed).

The concentration profile of the p-type dopants can be determined by measuring the concentration of the p-type dopant element from the surface of the Si substrate 100 on the anode side of the diode 1 using SIMS (Secondary Ion Mass Spectrometry). Meanwhile, the concentration profile of the activated dopants can be determined by measuring a distribution of SR (Spreading Resistance) in the depth direction and converting the measured SR value into the concentration of carriers.

In the present invention, the activation rate is defined as the (carrier concentration determined in the SR measurement)/(p-type dopant concentration determined in the SIMS measurement). The carrier concentration is the concentration of the activated p-type dopants determined in the SR measurement.

In a region A which is from the surface (at the depth of 0 μm) of the Si substrate 100 on the anode side to the depth of about 0.3 μm, the dopant concentration determined in the SIMS measurement and the carrier concentration determined in the SR measurement are both as high as about 1×10¹⁸ cm⁻³, and are constant values. Such a region is a region in which boron ions have been implanted at a high concentration as the p-type dopants for forming the anode p layer 102. As the crystals around the surface of the Si substrate 100 on the anode side have been melted by laser annealing, a box-shaped profile results. Such a region A corresponds to the anode p layer 102.

When the carrier concentration of the region A is too low, the number of holes that are injected from the anode electrode 109 is too small when current flows through the diode, so that a forward voltage of the diode 1 will increase. Meanwhile, when the carrier concentration of the region A is too high, the carrier concentration on the anode side increases and the carrier concentration on the cathode side decreases when current flows through the diode. Thus, the peak current during the reverse recovery becomes large, and a sharp rise in voltage/ringing thus becomes likely to occur. Accordingly, the carrier concentration of the anode p layer 102 is desirably greater than or equal to 1×10¹⁶ cm⁻³ and less than or equal to 1×10¹⁹ cm⁻³.

The activation rate of the n-type dopants in the region A of the box-shaped profile, which shows the anode p layer 102, is about 20 to 100% depending on the energy of laser irradiation. It should be noted that regarding the anode n layer 112, it is acceptable as long as the carrier concentration is in the aforementioned concentration range even if the activation rate is less than 100%.

It should be noted that sufficient accuracy cannot be obtained at present for the activation rate of a region where the concentration of the n-type dopants rapidly decreases in a region at a depth of around 0.3 μm from the surface of the Si substrate 100 on the anode side. Thus, detailed consideration therefor is omitted herein. Sufficient accuracy cannot be obtained because sufficient accuracy is not obtained for the origin in the depth direction in the SR measurement and also because the accuracy of the SR measurement decreases around the PN junction due to the influence of a depletion layer.

Regions at a depth of up to 0.3 to 1.7 μm from the surface of the Si substrate 100 on the anode side (i.e., region B and region C) are the regions where p-type dopants have been implanted to form the anode p− layer 103. In such regions, the region B at a depth of up to 0.3 to 1.0 μm has almost the same p-type dopant concentration determined in the SIMS measurement as the carrier concentration determined in the SR measurement, and thus has an activation rate of almost 100%. This is because heat that is provided to the surface of the Si substrate 100 on the cathode side by laser irradiation has sufficiently reached a region at a depth of 1.0 μm and thus has sufficiently activated the p-type dopants. Such a region B corresponds to the electrically effective anode p− layer 103.

The region C, which corresponds to a portion deeper than 1.0 μm, is a region in which the carrier concentration determined in the SR measurement is lower than the p-type dopant concentration determined in the SIMS measurement and the activation rate of the p-type dopants is thus low. Such a region includes a region where the activation rate is less than 1% as the heat of laser irradiation has not sufficiently reached the region and defects generated by ion implantation thus remain therein. As the defects remain, the region C is a region with a short carrier lifetime. Such a region C corresponds to the low-lifetime region layer 104. The low-lifetime region layer 104 can be defined as a region with an activation rate of less than 1%, for example. By setting the activation rate to less than 1%, it is possible to obtain a sufficient effect of suppressing a sharp rising voltage/ringing during recovery.

A region D at a depth of greater than or equal to 1.7 μm is a region where p-type dopant ions have not been implanted, and corresponds to the n− drift layer 101.

In the example shown in FIG. 9, the depth of the peak concentration of the p-type dopant ions implanted to form the anode p− layer 103 is about 1.5 μm. Meanwhile, the depth of the peak of the amount of defects is, about equal to the depth of the peak concentration of boron when boron ions are implanted with high energy as the p-type dopant ions, and is about 1.5 μm in the example shown in FIG. 9. The peak concentration of defects can be known from the position of the peak concentration of the dopant concentration, and can also be known from computation or process simulation using energy that is necessary for Si atoms to vary, for example. The “defects” herein means defects which are generated by ion implantation and are a source of recombination.

In the example shown in FIG. 9, the depth at which the implanted p-type dopant ions are sufficiently activated by laser annealing to reach a peak concentration is about 1.0 μm. Thus, the depth of the peak concentration of defects (1.5 μm) is deeper.

In order to set the depth of the peak concentration of defects generated by ion implantation to be deeper than the depth of the peak concentration of the p-type dopants activated by laser annealing, the distribution of the defects is set deeper or the depth at which the p-type dopants are activated by laser annealing is set shallower.

In order to set the distribution of the defects deeper, a lighter element is used as the p-type dopant ions or the energy of ion implantation is set high. When proton (hydrogen) or He is used as the element to ion-implant defects, the range of the ion implantation becomes too wide, and huge particle irradiation equipment like cyclotron is needed. Thus, boron, which is the lightest element of all the p-type dopant elements used to form a p-type dopant layer in the production of LSI (large scale integrated circuit), is desirably used. Further, when the energy of ion implantation is set higher, p-type dopants can be implanted to a deeper position. At this time, the energy of ion implantation is preferably set high in the range of the system operation and in the range of keeping the controllability necessary to generate a defect layer.

In order to set the depth at which the p-type dopants are activated by laser annealing to be shallower, energy that is transmitted to the Si substrate 100 by laser irradiation is set small or the wavelength of the laser is set short. Lowering the irradiation energy to less than 1.5 J/cm² shown as an example in FIG. 9 can set the depth of the activated p-type dopants to be further shallower. Further, shortening the laser irradiation time or reducing the number of times of laser irradiation can also set the depth of the activated p-type dopants to be shallow.

Regarding the wavelength of the laser, the second harmonic of a YLF laser with a wavelength of 536 nm is used in the example shown in FIG. 6. However, the depth of the activated p-type dopants can be made further shallower by using an XeCl excimer laser with a further shorter wavelength: 308 nm or a KrF excimer laser with a wavelength of 248 nm.

### Embodiment 1: Conclusion

As described above, the diode 1 in accordance with Embodiment 1 includes an anode p− layer 103 with a lower concentration of p-type dopants than the anode p layer 102, and the activation rate of the upper layer of the anode p− layer 103 is set higher than that of the lower layer thereof so as to form a low-lifetime region layer 104 below the anode p− layer 103. It is acceptable as long as the depth at which the p-type dopants are activated to form the low-lifetime region layer 104 is within the thickness of the anode p− layer 103. Thus, the depth of activation need not be strictly identical to the thickness of the anode p layer 102. That is, as a margin for the depth of activation by means of laser annealing is provided, there is no possibility that the electrical characteristics of the diode 1 will vary greatly even if the depth varies slightly. That is, it is possible to obtain the diode 1 that has small variations in the electrical characteristics and has a suppressed sharp rising voltage/ringing during reverse recovery without using large-scale equipment like cyclotron.

### Embodiment 2

FIG. 10 is a side sectional view of a diode 1 in accordance with Embodiment 2 of the present invention. FIG. 10 shows a schematic sectional view of an active region and a termination region of the diode 1 in accordance with Embodiment 2 as in FIG. 1. As shown in FIG. 10, the diode 1 in accordance with Embodiment 2 has a p-type well 105 with a HIRC structure that is formed over the entire surface of the active region in addition to the termination region.

In Embodiment 2, the p-type well 105 with a HIRC structure is formed in the active region before the anode p layer 102, the anode p− layer 103, and the low-lifetime region layer 104 are formed, as with the production method described with reference to FIGS. 2 and 8. The dose of the p-type dopants implanted into the Si substrate 100 in forming the p-type well 105 is set greater than or equal to 1×10¹¹ cm⁻² and less than or equal to 1×10¹³ cm⁻². In order to ensure the breakdown voltage of the termination structure, it is desirable to use the same FLR structure of the termination region as that in Embodiment 1 and set the concentration of p-type dopants in the p-type well 106 with the FLR structure of the diode 1 in accordance with Embodiment 2 to be higher than the concentration of p-type dopants in the p-type well 105 with the HIRC structure in the active region. The p-type well 105 with the HIRC structure and the p-type well 106 with the FLR structure may be formed separately, or be formed at the same time by locally providing an opening in a mask for the active region and thus reducing the amount of p-type dopants implanted into the Si substrate 100.

In the diode 1 in accordance with Embodiment 2, the p-type well 105 covers the low lifetime region layer 104. Thus, an electric field that is applied to the low-lifetime region layer 104 upon application of a reverse voltage becomes low, and the amount of leak current can thus be reduced. In addition, as the concentration of the p-type dopants in the p-type well 105 is low and holes are injected from the anode p layer 102 when current flows through the diode, it is possible to obtain the effect of suppressing a sharp rising voltage/ringing during reverse recovery as in Embodiment 1.

### Embodiment 3

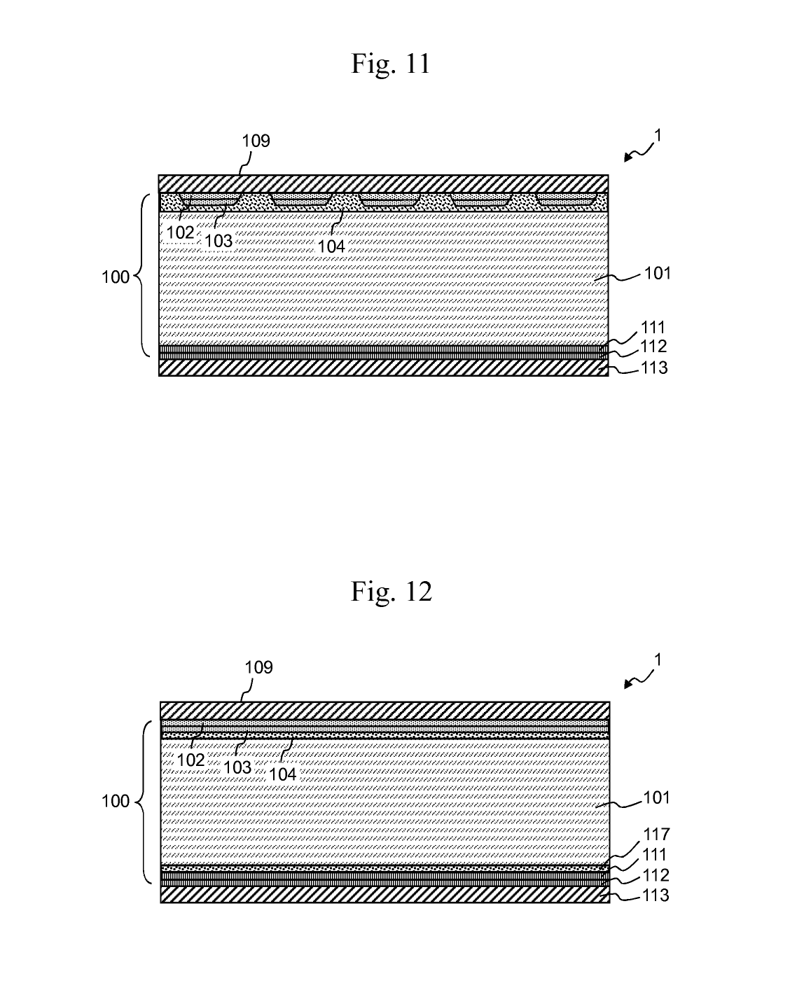

FIG. 11 is a side sectional view of a diode 1 in accordance with Embodiment 3 of the present invention. FIG. 11 shows a schematic sectional view of an active region of the diode 1 in accordance with Embodiment 3. Although the description of the termination region is omitted herein, it is the same as those in Embodiments 1 to 2.

As shown in FIG. 11, the diode 1 in accordance with Embodiment 3 has the anode p layer 102 and the anode p− layer 103 that are formed not over the entire surface of the active region but in a part of the active region. It is possible to form the anode p layer 102 and the anode p− layer 103 only in a part of the active region by irradiating not the entire surface of the active region but only a part of the active region with laser. The anode p layer 102 and the anode p− layer 103 are preferably formed in a stripe shape when seen from the surface of the Si substrate 100.

The diode 1 in accordance with Embodiment 3 has regions in which the anode p layer 102 and the anode p− layer 103 are not formed in the active region, and electrons pass through such regions toward the anode electrode when current flows through the diode. As a result, the number of holes that are injected from the anode p layer 102 is reduced, and a sharp rising voltage/ringing during reverse recovery can be further suppressed.

It is also possible to form a p− layer with a low activation rate of p-type dopants by irradiating a region in which the anode p layer 102 and the anode p− layer 103 are not formed in the plane of the active region shown in FIG. 11 with laser with lower energy than that used to form the anode p layer 102 and the anode p− layer 103. Accordingly, as electrons pass through the p− layer toward the anode electrode, a sharp rising voltage/ringing during recovery is further suppressed in the same way. Further, when a PN junction is provided by forming a p− layer, the stability of the junction is increased and yields are improved.

In the diode 1 in accordance with Embodiment 3, a p-type well 105 with a HIRC structure may be formed over the entire surface of the active region in addition to the termination region as with the diode 1 in accordance with Embodiment 2. Accordingly, an electric field that is applied to the low-lifetime region layer 104 upon application of a reverse voltage becomes low, and the amount of leak current can thus be reduced.

### Embodiment 4

FIG. 12 is a side sectional view of a diode 1 in accordance with Embodiment 4 of the present invention. FIG. 12 shows a schematic sectional view of an active region of the diode 1 in accordance with Embodiment 4. Although the description of the termination region is omitted herein, it is the same as those in Embodiments 1 to 3.

As shown in FIG. 12, the diode 1 in accordance with Embodiment 4 has a low-lifetime region layer 117, which is formed by defects introduced by the implantation of n-type dopant ions for the cathode buffer n layer on the cathode side, in addition to the structure of the diode 1 in accordance with Embodiment 1. The structure on the anode side is the same as that of the diode 1 in accordance with Embodiment 1.

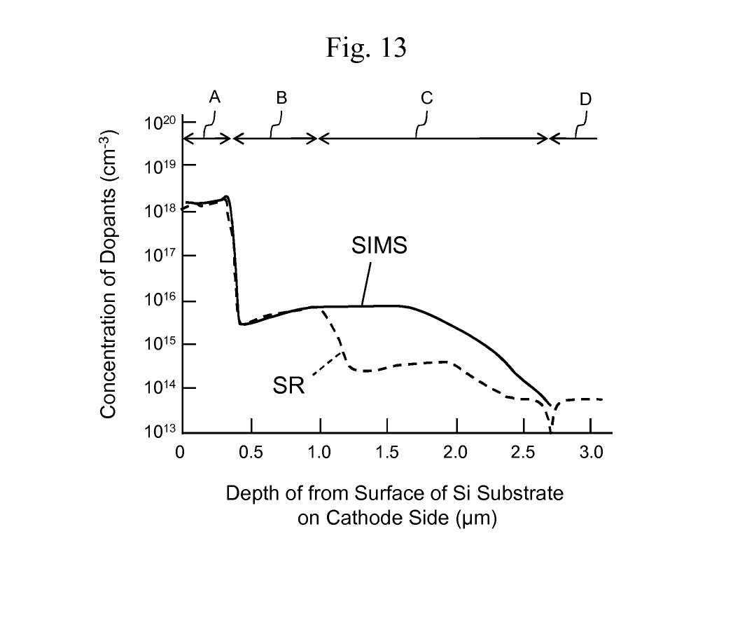

FIG. 13 is a view showing a concentration profile of n-type dopants (solid line: measured by SIMS) and a concentration profile of activated n-type dopants (dashed line: measured by SR) in the depth direction seen from the back surface of the Si substrate 100, that is, the cathode side in Embodiment 4. The structure of the n-type semiconductor layer on the cathode side in the depth direction will be described with reference to FIG. 13.

A region A corresponds to a cathode n layer 112 with a high concentration (1×10¹⁹ cm⁻³) of n-type dopants and a high activation rate (20 to 100%). A region B corresponds to a cathode buffer n layer 111 with a low concentration (about 1×10¹⁶ cm⁻³) of n-type dopants and a high activation rate (almost 100%). A region C corresponds to a low-lifetime region layer 117 in which the lifetime of minority carriers is short because the heat of laser irradiation has not reached this region and the defects generated by ion implantation thus remain therein. A region D corresponds to the n− drift layer 101 to which n-type dopant ions have not been implanted.

In Embodiment 1, unless an electron beam is irradiated to reduce the lifetime of the entire region in the n− drift layer 101, the tail current when recovery current is recovered during reverse recovery will increase, which results in increasing the recovery loss. In Embodiment 4, the low-lifetime region layer 117 is provided on the cathode side, which enables that the number of carriers that remain in the n− drift layer 101 on the cathode side during recovery is reduced and the tail current is thus reduced, whereby recovery loss can be reduced. That is, it is possible to suppress a sharp rising voltage/ringing during reverse recovery and thus reduce the recovery loss only by providing the low-lifetime region layer 104 on the anode side and the low-lifetime region layer 117 on the cathode side without controlling the lifetime by electron beam irradiation.

### Embodiment 5

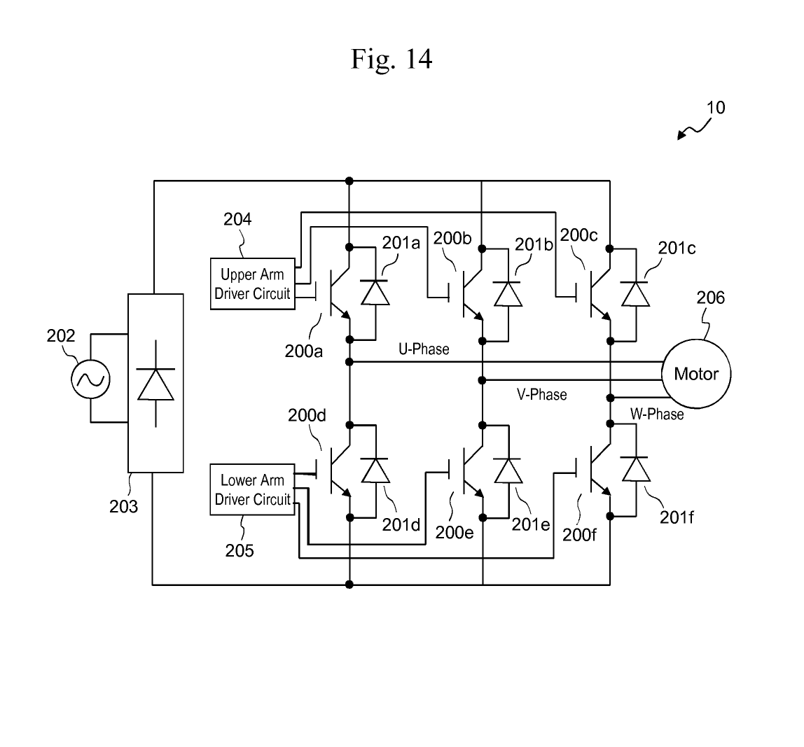

FIG. 14 is a circuit diagram of the electrical power conversion system 10 in accordance with Embodiment 5 of the present invention. The electrical power conversion system 10 shown in FIG. 14 is a system for converting power using the diode 1 described in any of Embodiments 1 to 4.

As shown in FIG. 14, the electrical power conversion system 10 includes a three-phase inverter circuit for driving a motor. Diodes 201a to 201f in accordance with the present invention are connected in inverse-parallel with IGBTs 200a to 200f that are semiconductor switching elements, respectively. That is, the diodes 201a to 201f operate as free wheeling diodes. The diode 1 in accordance with any of Embodiments 1 to 4 is used as each of the diodes 201a to 201f. Each one of the IGBTs 200a to 200c and each one of the IGBTs 200d to 200f are combined such that the two are connected in series. That is, two inverse parallel circuits each having an IGBT and a diode are connected in series, and constitute a half-bridge circuit for one phase.

The same number of half-bridge circuits as the number of phases of alternating current, that is, three phases are provided in Embodiment 5. Alternating-current output is provided from a series connection point of the two transistors: the IGBT 200a and the IGBT 200d, that is, a series connection point of the two inverse parallel circuits, and is connected as a U-phase alternating-current output to a motor 206, such as an induction machine, a synchronous machine, or the like. The other half-bridge circuits also provide V-phase and W-phase alternating-current outputs from the respective series connection points of the two IGBTs, and are connected to the motor 206.

The collectors of the IGBTs 200a to 200c on the upper arm side are commonly connected and are connected to the direct-current high potential side of a rectifier circuit 203. The emitters of the IGBTs 200d to 200f on the lower arm side are commonly connected, and are connected to the earth side of the rectifier circuit 203. The rectifier circuit 203 converts alternating current of the alternating-current power supply 202 into direct current. The IGBTs 200a to 200f are switched on and off to convert direct current received from the rectifier circuit 203 into alternating current and thus drive the motor 206. An upper arm driver circuit 204 and a lower arm driver circuit 205 provide drive signals to the IGBTs 200a to 200c on the upper arm side and the IGBTs 200d to 200f on the lower arm side, respectively, to switch the IGBTs 200a to 200f on and off.

According to Embodiment 5, the diodes 1 in accordance with the present invention are connected in inverse-parallel with the IGBTs 200a to 200f as free wheeling diodes. Thus, a sharp rising voltage/ringing of the diodes during switching can be suppressed. In addition, noise generated by voltage fluctuation can also be reduced. Further, as the recovery current of the diodes 1 are reduced, the switching loss can be reduced and the energy efficiency of the entire electrical power conversion system 10 can thus be improved. As a sharp rising voltage/ringing of the diodes 1 can be suppressed, the switching speed can be increased and the energy efficiency of the entire electrical power conversion system 10 can thus be improved.

It should be noted that the present invention is not limited to the aforementioned embodiments, and includes a variety of variations. For example, although the aforementioned embodiments have been described in detail to clearly illustrate the present invention, the present invention need not include all of the structures described in the embodiments. It is possible to replace a part of a structure of an embodiment with a structure of another embodiment. In addition, it is also possible to add, to a structure of an embodiment, a structure of another embodiment. Further, it is also possible to, for a part of a structure of each embodiment, add/remove/substitute a structure of another embodiment.

For example, the diode 1 in accordance with the present invention may be applied as a diode incorporated as a reverse-conducting semiconductor switching element. It is also possible to use semiconductor switching elements, such as MOSFETs (Metal Oxide Semiconductor Field Effect Transistors), junction bipolar transistors, junction FETs, static induction transistors, or GTO thyristors (Gate Turn Off Thyristors) instead of the IGBTs 200a to 200f of the electrical power conversion system 10 shown in FIG. 14.

### EXAMPLES

Hereinafter, the evaluation results of the operating characteristics will be described regarding the diode 1 in accordance with Embodiment 1 as Example 1 and regarding the diode 1 in accordance with Embodiment 4 as Example 2.

### (Fabrication Conditions)

For each of the diodes 1 in accordance with Example 1 and Example 2, an n-type Si wafer with a resistivity of 25 Ω·cm was used as the Si substrate 100.

As the p-type dopants for forming the anode p− layer 103 on the surface of the Si substrate 100 on the anode side, boron was implanted with an energy of 720 keV, an off-angle of 0°, and a dose of 1−10¹²/cm². As the p-type dopants for forming the anode p layer 102, boron was implanted with an energy of 25 keV, an off-angle of 7°, and a dose of 1×10¹⁴/cm². After that, the Si substrate was irradiated with the second harmonic of a YLF laser with an energy of 1.5 J/cm₂ as the laser annealing for activating the implanted p-type dopants.

The thickness of the Si substrate 100 was reduced to 120 μm from the back surface side. Then, phosphorus was implanted with an energy of 720 keV, an off-angle of 0°, and a dose of 1×10¹² cm⁻² to the back surface of the Si substrate 100 on the cathode side, as the n-type dopants for forming the cathode buffer n layer 111. In addition, phosphorus was implanted with an energy of 60 keV, an off-angle of 7°, and a dose of 1×10¹⁵ cm⁻², as the n-type dopants for the cathode n layer 112. After that, the Si substrate was irradiated with the second harmonic of a YLF laser with a wavelength of 536 nm as the laser annealing for activating the implanted n-type dopants. The structure of Example 1 was formed so as not to include the low-lifetime region layer 117 on the cathode side by setting the energy of the laser to 2.0 J/cm². The structure of Example 2 was formed so as to include the low-lifetime region layer 117 on the cathode side by setting the energy of the laser to 1.5 J/cm².

As Comparative Example 1, the irradiation energy of laser annealing for activating the p-type dopant ions implanted on the anode side of the diode of Example 1 was set as high as 2.0 J/cm². The ion implantation conditions and the other conditions in Comparative Example 1 are the same as those in Example 1. That is, Comparative Example 1 includes the anode p layer 102 and the anode p-layer 103, but does not include the low-lifetime region layer 104 on the anode side.

As Comparative Example 2, p-type dopant ions for forming the anode p− layer 103 was not implanted, and the energy for implanting p-type dopant ions for forming the anode p layer 102 was set to 130 keV in the diode of Example 1. The laser annealing conditions and the other conditions in Comparative Example 2 are the same as those in Example 1. That is, Comparative Example 2 includes the anode p layer 102 and the low-lifetime region layer 104 on the anode side, but does not include the anode p− layer 103.

### (Effects of Low-Lifetime Region Layer 104 on the Anode Side)

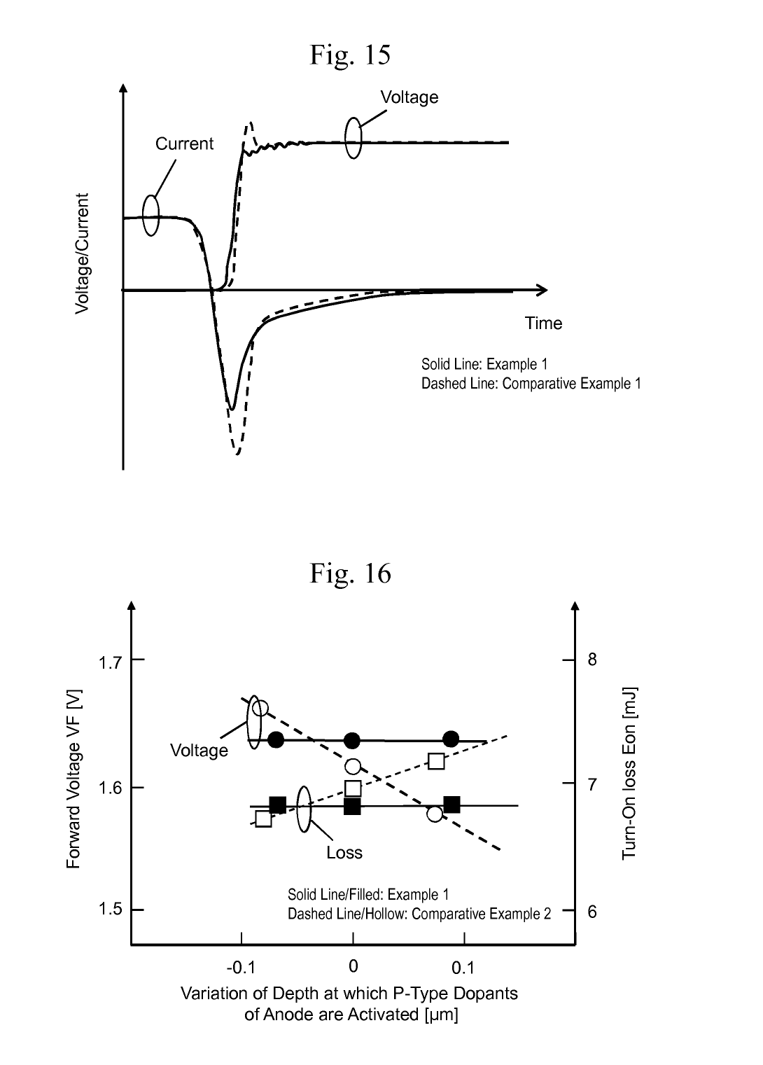

FIG. 15 is a diagram showing the current waveforms and the voltage waveforms of the recovery characteristics at room temperature of the diode of Example 1 (solid line) and the diode of Comparative Example 1 (dashed line). The effects of the low-lifetime region layer 104 on the anode side will be confirmed with reference to FIG. 15. The low-lifetime region layer 104 on the anode side is provided in Example 1 but not in Comparative Example 1.

Referring to the waveforms shown in FIG. 15, the peak current during recovery is smaller in Example 1 than in Comparative Example 1. This is because the low-lifetime region layer 104 on the anode side reduces the number of holes injected from the anode p layer and thus reduces the carrier density in the n− drift layer 101 on the anode side. As the peak current during recovery becomes small, turn-on loss of the IGBT becomes small. Further, because of the small recovery current, the time change rate of the current di/dt becomes smaller and the sharp rising voltage that occurs due to di/dt and the inductance of the main circuit becomes smaller in Example 1 than in Comparative Example 1. Further, in Example 1, the number of holes injected from the anode p layer is reduced and the carrier density in the n− drift layer 101 on the cathode side is thus increased. As a result, the number of carriers that remain in the n− drift layer 101 on the cathode side after the expansion of the depletion layer during reverse recovery is increased, whereby ringing becomes unlikely to occur during reverse recovery.

(Effects of Anode p− Layer 103)

FIG. 16 is a diagram showing a forward voltage and turn-on loss at 150° C. when the depth at which the p-type dopants are activated by laser annealing on the anode side varies in each of Example 1 (solid line) and Comparative Example 2 (dashed line).

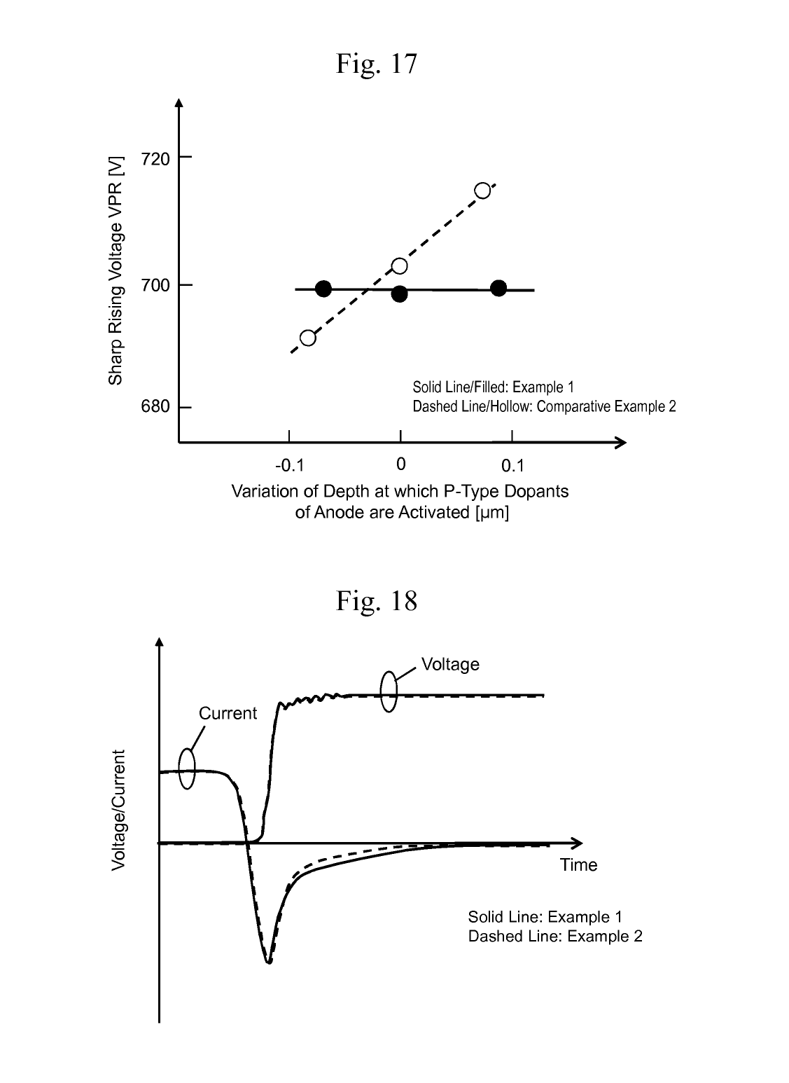

FIG. 17 is a diagram showing a sharp rising voltage during recovery at room temperature when the depth at which the p-type dopants are activated by laser annealing on the anode side varies in each of Example 1 (solid line) and Comparative Example 2 (dashed line).

In Example 1, the anode p− layer 103 formed by ion implantation with high energy is provided between the anode p layer 102 and the low-lifetime region layer 104. In Comparative Example 2, the anode p− layer 103 is not provided, and the anode p layer 102 is in direct contact with the low-lifetime region layer 104.

As can be seen from FIGS. 16 and 17, a forward voltage, turn-on loss, and a sharp rising voltage when the depth at which the p-type dopants are activated by laser annealing on the anode side varies do not change almost at all in Example 1 but change greatly in Comparative Example 2. The change in Comparative Example 2 is large because when the depth at which the p-type dopants are activated changes, the amount of defects that remain in the low-lifetime region layer 104 of the anode changes greatly. The change in Example 1 is small because the depth at which the defect density in the low-lifetime region layer 104 is peak is greater than the depth at which the p-type dopants are activated, and thus the amount of defects that remain in the low-lifetime region layer 104 does not change greatly even if the depth at which the p-type dopants are activated changes. That is, it is possible to suppress variations in the electrical characteristics of the diode, such as a forward voltage, turn-on loss, and a sharp rising voltage by setting the depth at which the density of defects, which are formed by implantation of p-type dopant ions, is peak to be deep.

### (Effects of Providing Low Lifetime Region Layer on Each of the Anode Side and the Cathode Side)

FIG. 18 is a diagram showing current waveforms and voltage waveforms of the recovery characteristics at room temperature of Example 1 (solid line) and Example 2 (dashed line). The effects of providing a low-lifetime region layer on each of the anode side and the cathode side as shown in FIG. 12 will be confirmed with reference to FIG. 18. In Example 1, the low-lifetime region layer 104 is provided only on the anode side, while in Example 2, a low-lifetime region layer is provided on each of the anode side and the cathode side.

From the waveforms shown in FIG. 18, it is seen that a sharp rising voltage during recovery as well as the peak current during recovery is the same between Example 1 and Example 2. This is because the anode structure is the same and the number of holes that are injected from the anode is thus the same. The tail current during the latter half of the recovery period is reduced in Examples 2 than in Example 1. This is because the low-lifetime region layer 117 provided on the cathode side reduces the carriers that remain on the cathode side during the latter half of the recovery period. With the reduction in the tail current, the recovery loss is reduced in Example 2 than in Example 1. In order to reduce the tail current and thus reduce recovery loss in Example 1, it is necessary to control the lifetime of the entire region of the n− drift layer 101 through electron beam irradiation. In contrast, in Example 2, electron beam irradiation is not performed but the same laser annealing is performed on each of the anode side and the cathode side, whereby it is possible to reduce recovery loss while suppressing a sharp rising voltage during recovery.

### REFERENCE SIGNS LIST

1 Diode
10 Electrical power conversion system
100 Si substrate
101 n− drift layer
102 Anode p layer
103 Anode p− layer
104 Low-lifetime region layer
105 P-type well region with HIRC structure
106 P-type well region with FLR structure
107 n-type well region
108 Oxide film
109 Anode electrode
110 Field plate electrode
111 Cathode buffer n layer
112 Cathode n layer
113 Cathode electrode
114 to 116 Resist
117 Low lifetime region layer
200a to 200f IGBT
201a to 201f Diode
202 Alternating current power supply
203 Rectifier circuit
204 Upper arm driver circuit
205 Lower arm driver circuit
206 Motor

1. A diode comprising:
a first semiconductor layer of a first conductivity type;
a second semiconductor layer of the first conductivity type, the second semiconductor layer being provided adjacent to the first semiconductor layer and having a higher concentration of dopants of the first conductivity type than the first semiconductor layer;
a third semiconductor layer of a second conductivity type, the third semiconductor layer being provided adjacent to the first semiconductor layer and provided on a side opposite to a side on which the second semiconductor layer is provided;
a fourth semiconductor layer of a second conductivity type, the fourth semiconductor layer being provided adjacent to the third semiconductor layer and provided between the first semiconductor layer and the third semiconductor layer;
a first electrode that is ohmic-connected to the third semiconductor layer; and
a second electrode that is ohmic-connected to the second semiconductor layer, wherein
the fourth semiconductor layer is configured such that a concentration of dopants of the second conductivity type is lower than that of the third semiconductor layer, and
the fourth semiconductor layer has formed therein a layer having a different ratio of a concentration of carriers to a concentration of dopants of the second conductivity type from other portions, the concentration of carriers being determined on the basis of measurement of spreading resistance, and the concentration of the dopants of the second conductivity type being determined using a secondary ion mass spectrometry.

2. The diode according to claim 1, wherein the layer, which has the different ratio of the concentration of carriers to the concentration of the dopants of the second conductivity type from the other portions, in the fourth semiconductor layer is formed as a low-lifetime region layer with a lower lifetime of minority carriers than the other portions of the fourth semiconductor layer.

3. The diode according to claim 2, wherein
the fourth semiconductor layer is formed by a low-dopant-concentration layer and the low-lifetime region layer, the dopant-concentration layer being adjacent to the third semiconductor layer and the low-lifetime region layer being adjacent to the first semiconductor layer, and
the low-lifetime region layer being formed such that a ratio of a concentration of carriers to a concentration of dopants of the second conductivity type is lower than that of the low-dopant-concentration layer.

4. The diode according to claim 3, wherein the low-lifetime region layer contains defects generated by implantation of dopant ions of the second conductivity type into the fourth semiconductor layer.

5. The diode according to claim 4, wherein the fourth semiconductor layer is formed such that a depth at which a density of the defects is maximum from a plane of the third semiconductor layer in contact with the first electrode is formed to be deeper than a boundary between the low-lifetime region layer and the low-dopant-concentration layer from the plane of the third semiconductor layer in contact with the first electrode.

6. The diode according to claim 1, wherein an element of the dopants of the second conductivity type contained in the low-lifetime region layer is boron.

7. The diode according to claim 1, further comprising a fifth semiconductor layer of the second conductivity type between the first semiconductor layer and the low-lifetime region layer, the fifth semiconductor layer having a lower concentration of dopants of the second conductivity type than the third semiconductor layer.

8. The diode according to claim 1, wherein the third semiconductor layer and the fourth semiconductor layer are formed in a stripe pattern on a surface of the first semiconductor substrate on an anode side.

9. The diode according to claim 1, further comprising a sixth semiconductor layer between the first semiconductor layer and the second semiconductor layer, the sixth semiconductor layer containing a same type of dopants as the dopants of the first conductivity type contained in the second semiconductor layer and having a lower lifetime of minority carriers than the first semiconductor layer.

10. An electrical power conversion system comprising:
a semiconductor switching element; and
the diode according to claim 1, the diode being connected in inverse-parallel with the semiconductor switching element.
